(19) United States
(12) Patent Application Publication
(10) Pub. No.: US 2011/0180898 A1
(43) Pub. Date: Jul. 28, 2011

(54) SEMICONDUCTOR DEVICE

(75) Inventors: Atsushi Tomishima, Chiba (JP); Yoshinori Fukuba, Kanagawa (JP); Shigeo Kida, Chiba (JP); Akira Yamaguchi, Saitama (JP)

(73) Assignee: KABUSHIKI KAISHA TOSHIBA, Tokyo (JP)

(21) Appl. No.: 12/883,653

(22) Filed: Sep. 16, 2010

(30) Foreign Application Priority Data
Jan. 27, 2010 (JP) 2010-015772

(51) Int. Cl. H01L 29/92

(52) U.S. Cl. 257/532; 257/E29.342

(57) ABSTRACT

According to the embodiments, a core block is formed on a semiconductor chip, and is constructed of an integrated circuit that can operate independently. A power-supply switch is formed on the semiconductor chip, and connects or disconnects the core block to or from a power line. A capacitor is formed on the semiconductor chip, and is connected to the power line in parallel to the core block. A selection switch is formed on the semiconductor chip, and connects or disconnects the capacitor to or from the power line.

### CROSS-REFERENCE TO RELATED APPLICATIONS

This application is based upon and claims the benefit of priority from the prior Japanese Patent Application No. 2010-15772, filed on Jan. 27, 2010; the entire contents of which are incorporated herein by reference.

### FIELD

Embodiments described herein relate generally to a semiconductor device.

### BACKGROUND

A power supply network (e.g., a source of power supply, a power plane, a capacitor, or a power supply channel to a chip through a package) is generally optimized to achieve a stable operation of the whole system containing a chip component or a package component mounted on a board. In this case, it is extremely difficult to evaluate and examine a power-supply design in the time domain. Therefore, in general, voltage fluctuation in the time domain is optimized by analyzing power supply impedance between a power supply of a voltage supply source and the ground in the frequency domain and reducing the power supply impedance to be equal to or smaller than an acceptable value.

When the power supply network is not adequately optimized, power-supply voltage fluctuation is increased, which is the cause of increasing jitter or noise. These may lead to distortion of a signal waveform or increase a ringing, resulting in malfunction or the like. Furthermore, these may become a cause of noise transmission to other devices.

In particular, when the frequency at which self-antiresonance occurs (i.e., the impedance increases) due to an inductance component and a capacitance component of the system matches the operating frequency, the above-mentioned problem is actualized.

Therefore, in general, resonance analysis is performed on the system as a whole and measures are taken so that the resonance frequency does not match the operating frequency at the time the system is designed.

As one of the measures, a plurality of bulk capacitors and a plurality of decoupling capacitors are generally mounted on a board so that the impedance becomes equal to or smaller than a target value based on the analysis of the impedance of the system. The capacitors mounted on the board are effective in a frequency band from the DC domain to tens of MHz. Therefore, a system with a relatively low operating frequency can sufficiently be optimized by mounting the capacitors on the board.

Furthermore, the equivalent capacitance value of a chip influences the impedance in only the high frequency band of GHz or more. Therefore, the power-supply design of the whole system can be optimized even without considering such a high frequency band, and problems with malfunction or the like rarely occurs.

However, when the operating frequency of the system falls within a band from hundreds of MHz to GHz, the optimization by the method of mounting the capacitors on the board is not enough, and it is necessary to optimize the power-supply design of the whole system by taking the chip capacity into consideration.

Furthermore, Japanese Patent Application Laid-open No. 2009-176922 for example discloses a method in which a capacitance value of a decoupling capacitor component, which is connected to a power feed system of a memory LSI and of which capacitance value is variable, is dynamically controlled depending on the operation of the memory LSI in order to achieve broadband low impedance of the power feed system of the memory LSI with the decreased number of chip components.

### BRIEF DESCRIPTION OF THE DRAWINGS

FIG. 1 is a block diagram illustrating a general configuration of a semiconductor device according to a first embodiment of the present invention;

FIG. 2 is a diagram illustrating impedance frequency characteristics of the semiconductor device shown in FIG. 1;

FIG. 3 is a block diagram illustrating a general configuration of a semiconductor device according to a second embodiment of the present invention;

FIG. 4 is a block diagram illustrating a general configuration of a semiconductor device according to a third embodiment of the present invention;

FIG. 5 is a block diagram illustrating a general configuration of a semiconductor device according to a fourth embodiment of the present invention;

FIG. 6 is a diagram illustrating a general configuration of a semiconductor device according to a fifth embodiment of the present invention;

FIG. 7 is a cross-sectional view explaining a general configuration of a semiconductor device according to a sixth embodiment of the present invention;

FIG. 8 is a cross-sectional view explaining a general configuration of a semiconductor device according to a seventh embodiment of the present invention; and

FIG. 9 is a cross-sectional view explaining a general configuration of a semiconductor device according to an eighth embodiment of the present invention.

### DETAILED DESCRIPTION

In general, according to one embodiment, a semiconductor device includes a core block, a power-supply switch, a capacitor, and a selection switch. The core block is formed on a semiconductor chip, and is constructed of an integrated circuit that can operate independently. The power-supply switch is formed on the semiconductor chip, and connects or disconnects the core block to or from a power line. The capacitor is formed on the semiconductor chip, and is connected to the power line in parallel to the core block. The selection switch is formed on the semiconductor chip, and connects or disconnects the capacitor to or from the power line.

Exemplary embodiments of a semiconductor device according to the present invention will be explained in detail below with reference to the accompanying drawings. The present invention is not limited by the following embodiments.

### First Embodiment

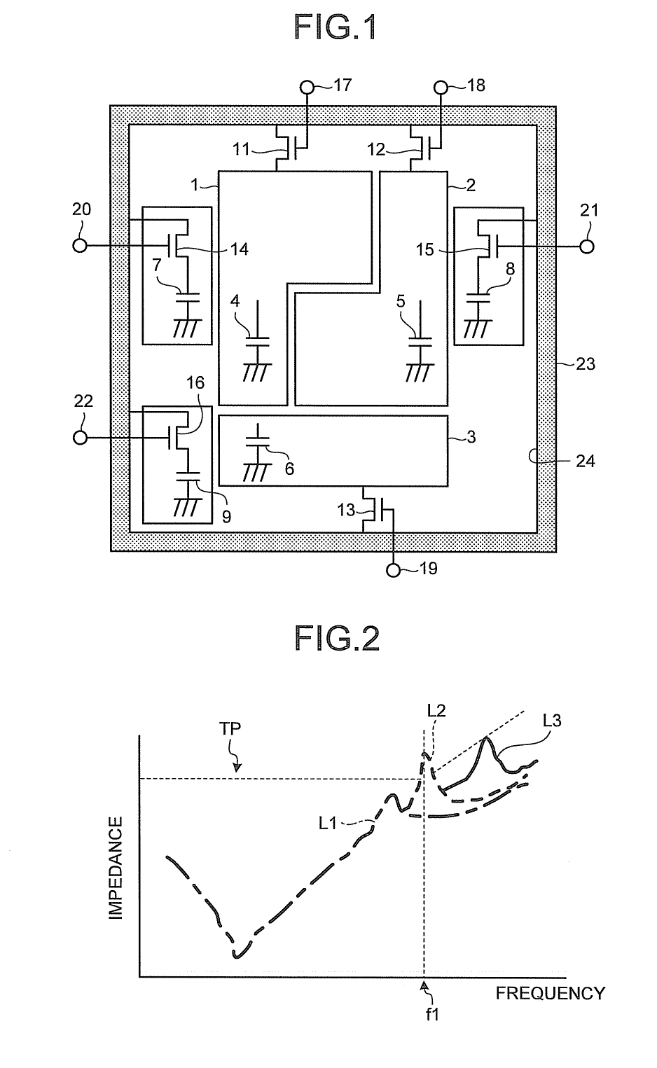

FIG. 1 is a block diagram illustrating a general configuration of a semiconductor device according to a first embodiment of the present invention.

In FIG. 1, core blocks 1 to 3 are formed on a semiconductor chip 23. Each of the core blocks 1 to 3 is constructed of an integrated circuit that can operate independently. The core blocks 1 to 3 may be core processors or memory blocks for example.

A power line 24 is also formed on the semiconductor chip 23 along the outer circumference of the semiconductor chip 23. The core blocks 1 to 3 are connected to the power line 24 via power-supply switches 11 to 13, respectively. Field-effect transistors for example may be used as the power-supply switches 11 to 13. Enable terminals 17 to 19 for turning on or off the power-supply switches 11 to 13 are arranged on the power-supply switches 11 to 13, respectively. Equivalent capacities 4 to 6 with reference to the power line 24 are formed in the core blocks 1 to 3, respectively.

Furthermore, capacitors 7 to 9 are formed on the semiconductor chip 23. The capacities of the capacitors 7 to 9 can be made equal to the equivalent capacities 4 to 6 of the core blocks 1 to 3. One ends of the capacitors 7 to 9 are connected to the power line 24 via selection switches 14 to 16, respectively. Field-effect transistors for example may be used as the selection switches 14 to 16. Enable terminals 20 to 22 for turning on or off the selection switches 14 to 16 are arranged on the selection switches 14 to 16, respectively.

When the core blocks 1 to 3 are to be operated, the power-supply switches 11 to 13 are turned on via the enable terminals 17 to 19, respectively, so that power is supplied to the core blocks 1 to 3 from the power line 24. Furthermore, by turning off the selection switches 14 to 16 via the enable terminals 20 to 22, respectively, the capacitors 7 to 9 are disconnected from the power line 24. At this time, the equivalent capacity of the semiconductor chip 23 with reference to the power line 24 becomes equal to the sum of the equivalent capacities 4 to 6 of the core blocks 1 to 3. By reducing the power supply impedance to be equal to or smaller than an acceptable value by optimizing a power supply network based on the equivalent capacity of the semiconductor chip 23 at this time, it is possible to optimize voltage fluctuation in the time domain.

On the other hand, when any of the core blocks 1 to 3 is kept operating and the rest of the core blocks 1 to 3 is stopped in order to save the power consumption, the equivalent capacity of the semiconductor chip 23 with reference to the power line 24 decreases. Therefore, in some cases, the power supply impedance optimized based on the sum of the equivalent capacities 4 to 6 of the core blocks may exceed the acceptable value.

In this case, when any of the core blocks 1 to 3 is stopped, and if one of the selection switches 14 to 16 corresponding to the stopped core block is turned on, one of the capacitors 7 to 9 corresponding to the stopped core block can be connected to the power line 24. Therefore, even when any of the core blocks 1 to 3 is stopped, the equivalent capacity of the semiconductor chip 23 with reference to the power line 24 can be made equal to the sum of the equivalent capacities 4 to 6 of the core blocks 1 to 3. Consequently, it is possible to reduce the power supply impedance to be equal to or smaller than the acceptable value without taking any measures on a board on which the semiconductor chip 23 is mounted. As a result, it is possible to optimize the voltage fluctuation in the time domain.

FIG. 2 is a diagram illustrating impedance frequency characteristics of the semiconductor device shown in FIG. 1.

In FIG. 2, the frequency characteristics of the power supply impedance when the core blocks 1 to 3 are operated is represented by L1, the frequency characteristics of the power supply impedance when the core blocks 1 and 2 are operated is represented by L2, and the frequency characteristics of the power supply impedance when the core blocks 1 and 3 or the core blocks 2 and 3 are operated is represented by L3.

Both when the core blocks 1 to 3 are operated and when the core blocks 1 and 3 or the core blocks 2 and 3 are operated, the power supply impedance is reduced to be equal to or smaller than a target impedance TP, and the operating frequency f1 does not match the antiresonance frequency. Therefore, the power supply network can fully be optimized, so that the power-supply voltage fluctuation can be reduced, resulting in suppressing jitter or noise.

On the other hand, when the core blocks 1 and 2 are operated, the power supply impedance exceeds the target impedance TP, and the operating frequency f1 matches the antiresonance frequency. Therefore, the power supply network cannot fully be optimized, so that the power-supply voltage fluctuation is increased, resulting in increasing jitter or noise.

To deal with this, when the core blocks 1 and 2 are operated, the selection switch 16 shown in FIG. 1 is turned on to connect the capacitor 8 to the power line 24. Consequently, the equivalent capacity of the semiconductor chip 23 with reference to the power line 24 can be made equal to the equivalent capacity which is obtained when the core blocks 1 to 3 are operated. Therefore, it is possible to reduce the power supply impedance to be equal to or smaller than the target impedance TP and prevent the operating frequency f1 from being matched with the antiresonance frequency without taking any measures on the board on which the semiconductor chip 23 is mounted.

### Second Embodiment

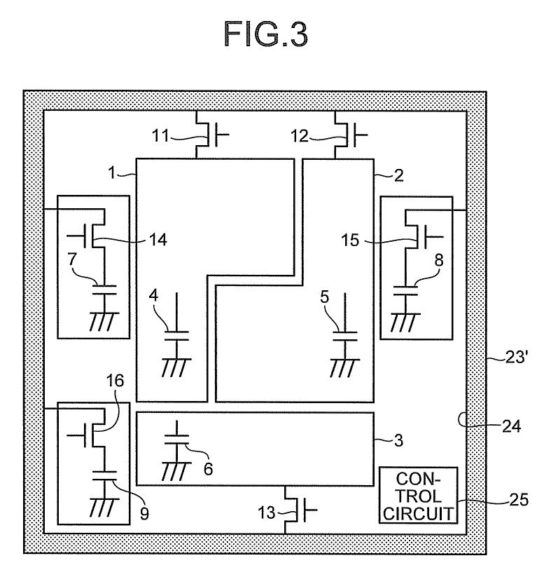

FIG. 3 is a block diagram illustrating a general configuration of a semiconductor device according to a second embodiment of the present invention.

In FIG. 3, a semiconductor chip 23′ includes a control circuit 25 in addition that it has the configuration of the semiconductor chip 23 shown in FIG. 1. The control circuit 25 can control a connection state between the capacitors 7 to 9 and the power line 24 depending on a connection state between the core blocks 1 to 3 and the power line 24. More specifically, the control circuit 25 turns on the selection switches 14 to 16 when the power-supply switches 11 to 13 are off, turns on the selection switches 14 and 15 when the power-supply switches 11 and 12 are off, turns on the selection switches 14 and 16 when the power-supply switches 11 and 13 are off, turns on the selection switches 15 and 16 when the power-supply switches 12 and 13 are off, turns on the selection switch 14 when the power-supply switch 11 is off, turns on the selection switch 15 when the power-supply switch 12 is off, and turns on the selection switch 16 when the power-supply switch 13 is off.

Therefore, even when any of the core blocks 1 to 3 is stopped, the equivalent capacity of the semiconductor chip 23 with reference to the power line 24 can be made equal to the sum of the equivalent capacities 4 to 6 of the core blocks 1 to 3 without inputting an enable signal from outside via the enable terminals 17 to 22 shown in FIG. 1.

### Third Embodiment

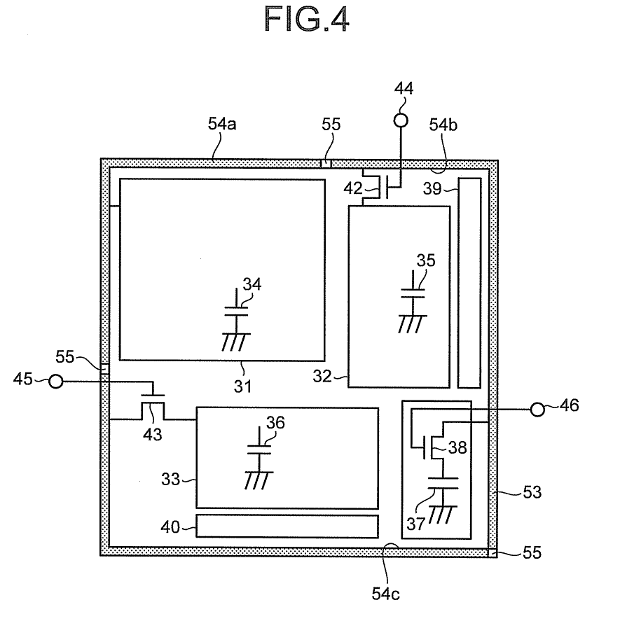

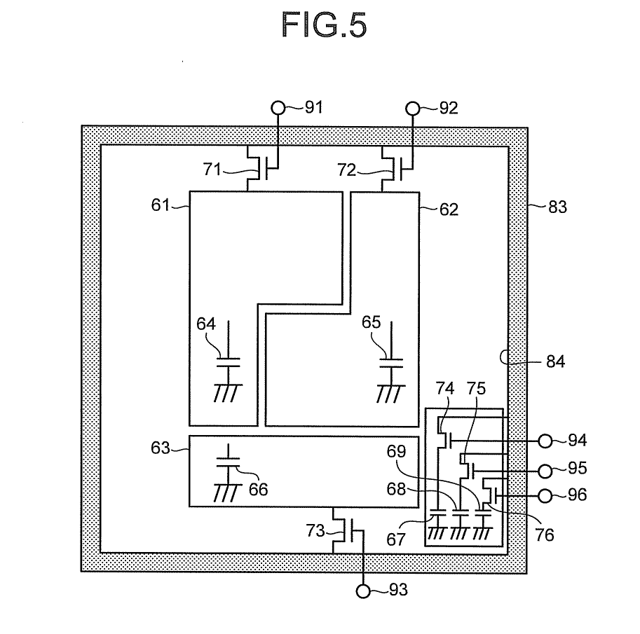

FIG. 4 is a block diagram illustrating a general configuration of a semiconductor device according to a third embodiment of the present invention.

In FIG. 4, core blocks 31 to 33 are formed on a semiconductor chip 53. Each of the core blocks 31 to 33 is constructed of an integrated circuit that can operate independently. The core blocks 31 to 33 can operate with a predetermined bit width. In particular, the core block 32 performs a process on upper bits, and the core block 33 performs a process on lower bits. An input-output circuit 39 for exchanging the upper bits is arranged adjacent to the core block 32, and an input-output circuit 40 for exchanging the lower bits is arranged adjacent to the core block 33.

Furthermore, power lines 54a to 54c are formed on the semiconductor chip 53 along the outer circumference of the semiconductor chip 53. The power lines 54a to 54c are separated from each other by cut cells 55. The core block 31 is connected to the power line 54a. The core blocks 32 and 33 are connected to the power lines 54b and 54c via power-supply switches 42 and 43, respectively. Enable terminals 44 and 45 for turning on or off the power-supply switches 42 and 43 are arranged on the power-supply switches 42 and 43, respectively. Equivalent capacities 34 to 36 with reference to the power lines 54a to 54c are formed in the core blocks 31 to 33, respectively.

Furthermore, a capacitor 37 is formed on the semiconductor chip 53. The capacity of the capacitor 37 can be made equal to the equivalent capacity 35 of the core block 32. One end of the capacitor 37 is connected to the power line 54b via a selection switch 38. An enable terminal 46 for turning on or off the selection switch 38 is arranged on the selection switch 38.

When the core blocks 31 to 33 are to be operated, the power-supply switches 42 and 43 are turned on via the enable terminals 44 and 45, respectively, so that power is supplied to the core blocks 32 and 33 from the power lines 54b and 54c, respectively. Furthermore, by turning off the selection switch 38 via the enable terminal 46, the capacitor 37 is disconnected from the power line 54b. At this time, the equivalent capacity of the semiconductor chip 53 with reference to the power lines 54a to 54c as a whole becomes equal to the sum of the equivalent capacities 34 to 36 of the core blocks 31 to 33. By reducing the power supply impedance to be equal to or smaller than the acceptable value by optimizing the power supply network based on the equivalent capacity of the semiconductor chip 53 at this time, it is possible to optimize the voltage fluctuation in the time domain.

On the other hand, when the upper bits are not used by an application, the power-supply switch 42 is turned off via the enable terminal 44, so that the power to the core block 32 is blocked. Furthermore, by turning on the selection switch 38 via the enable terminal 46, the capacitor 37 is connected to the power line 54b.

Therefore, even when the core block 32 is stopped, the equivalent capacity of the semiconductor chip 53 can be made equal to the sum of the equivalent capacities 34 to 36 of the core blocks 31 to 33. Consequently, it is possible to reduce the power supply impedance to be equal to or smaller than the acceptable value and optimize the voltage fluctuation in the time domain without taking any measures on a board on which the semiconductor chip 53 is mounted.

Similarly to the semiconductor chip 23′ shown in FIG. 3, it is possible to mount, on the semiconductor chip 53, a control circuit that controls a connection state between the capacitor 37 and the power line 54b depending on a connection state between the core blocks 31 to 33 and the power lines 54a to 54c.

### Fourth Embodiment

FIG. 5 is a block diagram illustrating a general configuration of a semiconductor device according to a fourth embodiment of the present invention.

In FIG. 5, core blocks 61 to 63 are formed on a semiconductor chip 83. Each of the core blocks 61 to 63 is constructed of an integrated circuit that can operate independently.

A power line 84 is also formed on the semiconductor chip 83 along the outer circumference of the semiconductor chip 83. The core blocks 61 to 63 are connected to the power line 84 via power-supply switches 71 to 73, respectively. Enable terminals 91 to 93 for turning on or off the power-supply switches 71 to 73 are arranged on the power-supply switches 71 to 73, respectively. Equivalent capacities 64 to 66 with reference to the power line 84 are formed in the core blocks 61 to 63, respectively.

Furthermore, capacitors 67 to 69 are formed on the semiconductor chip 83. The capacities of the capacitors 67 to 69 can be set to arbitrary values. One ends of the capacitors 67 to 69 are connected to the power line 84 via selection switches 74 to 76, respectively. Enable terminals 94 to 96 for turning on or off the selection switches 74 to 76 are arranged on the selection switches 74 to 76, respectively.

By turning on or off the power-supply switches 71 to 73 via the enable terminals 91 to 93, respectively, it is possible to operate any of the core blocks 61 to 63. Furthermore, by turning on or off the selection switches 74 to 76 via the enable terminals 94 to 96, respectively, it is possible to adjust the equivalent capacity of the semiconductor chip 83. Consequently, it is possible to reduce the power supply impedance to be equal to or smaller than the acceptable value and prevent the operating frequency from being matched with the antiresonance frequency without taking any measures on a board on which the semiconductor chip 83 is mounted.

Similarly to the semiconductor chip 23′ shown in FIG. 3, it is possible to mount, on the semiconductor chip 83, a control circuit that controls a connection state between the capacitors 67 to 69 and the power line 84 depending on a connection state between the core blocks 61 to 63 and the power line 84.

### Fifth Embodiment

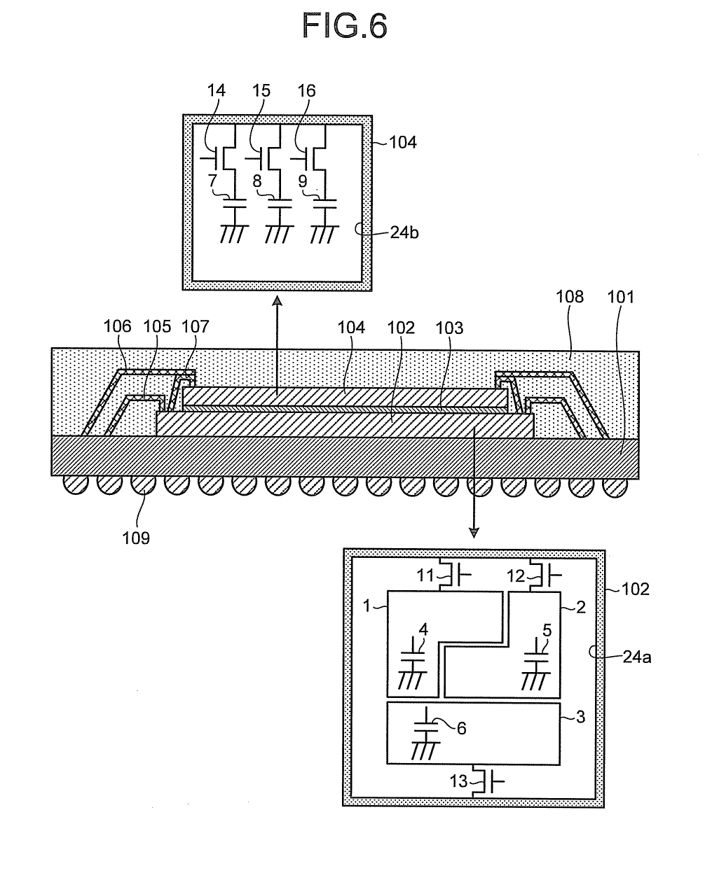

FIG. 6 is a diagram illustrating a general configuration of a semiconductor device according to a fifth embodiment of the present invention.

In FIG. 6, a semiconductor chip 102 is mounted with face up on a carrier substrate 101. Furthermore, an equivalent capacitance chip 104 is mounted with face up on the semiconductor chip 102 via a spacer layer 103.

As the carrier substrate 101, a double-sided substrate, a multilayer wiring substrate, a build-up substrate, a tape substrate, a film substrate or the like may be used. As a material for forming the carrier substrate 101, a polyimide resin, a glass epoxy resin, a BT resin, a composition of aramid and epoxy, a ceramic, or the like may be used.

Furthermore, the core blocks 1 to 3, the power-supply switches 11 to 13, and a power line 24a are formed on the semiconductor chip 102. The core blocks 1 to 3 are connected to the power line 24a via the power-supply switches 11 to 13, respectively. The equivalent capacities 4 to 6 with reference to the power line 24a are formed in the core blocks 1 to 3, respectively.

The spacer layer 103 may be, for example, a resin layer such as an epoxy layer, an insulating pressure-sensitive adhesive sheet, or an adhesive sheet.

Furthermore, the capacitors 7 to 9, the selection switches 14 to 16, and a power line 24b are formed on the equivalent capacitance chip 104. One ends of the capacitors 7 to 9 are connected to the power line 24b via the selection switches 14 to 16, respectively.

The semiconductor chip 102 is connected to the carrier substrate 101 via a bonding wire 105, and the equivalent capacitance chip 104 is connected to the carrier substrate 101 via a bonding wire 106. Also, the power line 24a of the semiconductor chip 102 and the power line 24b of the equivalent capacitance chip 104 are connected to each other via a bonding wire 107.

The semiconductor chip 102, the equivalent capacitance chip 104, and the bonding wires 105 to 107 are encapsulated by a sealing member 108, so that a semiconductor package is constructed. Furthermore, protruding electrodes 109 for mounting the semiconductor package on a board are formed on the back surface of the carrier substrate 101. As the sealing member 108, a molding resin or a potting resin using an epoxy resin or the like may be used. As the protruding electrodes 109, Au bump, Cu bump or Ni bump coated with a solder material, a solder ball or the like may be used.

Because the semiconductor chip 102 and the equivalent capacitance chip 104 are mounted on the same semiconductor package, even when any of the core blocks 1 to 3 is stopped, the equivalent capacity of the semiconductor chip 102 can be made equal to the sum of the equivalent capacities 4 to 6 of the core blocks 1 to 3 without taking any measures on the board on which the semiconductor package is mounted. Furthermore, it is possible to reduce the power supply impedance to be equal to or smaller than a defined value and prevent the operating frequency from being matched with the antiresonance frequency.

In the embodiment described with reference to FIG. 6, a method is explained in which the semiconductor chip 102 and the equivalent capacitance chip 104 implement the same functions as those of the semiconductor chip 23 shown in FIG. 1. However, it is possible to implement the same functions as those of the semiconductor chip 53 shown in FIG. 4, or the same functions as those of the semiconductor chip 83 shown in FIG. 5.

### Sixth Embodiment

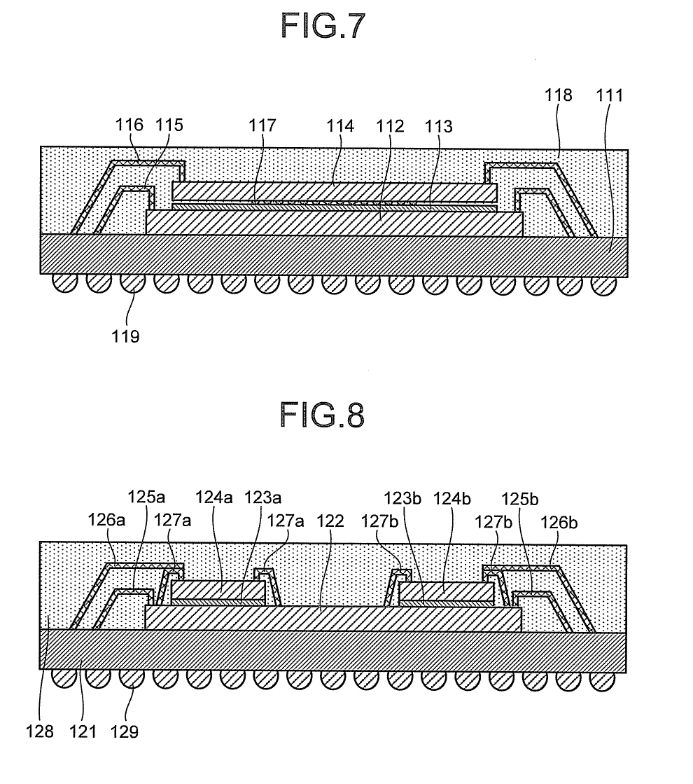

FIG. 7 is a cross-sectional view explaining a general configuration of a semiconductor device according to a sixth embodiment of the present invention.

In FIG. 7, a semiconductor chip 112 is mounted with face up on a carrier substrate 111. The semiconductor chip 112 is formed as a chip size package, and a wiring layer 113 is formed on the semiconductor chip 112. An equivalent capacitance chip 114 is mounted with face down on the wiring layer 113 on the semiconductor chip 112 via protruding electrodes 117. As the protruding electrodes 117, Au bump, Cu bump or Ni bump coated with a solder material, a solder ball, or the like may be used. A through electrode that pierces through the semiconductor chip 112 is formed on the semiconductor chip 112, so that the top surface and the bottom surface of the semiconductor chip 112 are electrically connected to each other.

Similarly to the semiconductor chip 102 shown in FIG. 6 for example, it is possible to form the core blocks 1 to 3, the power-supply switches 11 to 13, and the power line 24a on the semiconductor chip 112. Furthermore, similarly to the equivalent capacitance chip 104 shown in FIG. 6 for example, it is possible to form the capacitors 7 to 9, the selection switches 14 to 16, and the power line 24b on the equivalent capacitance chip 114.

The semiconductor chip 112 is connected to the carrier substrate 111 via a bonding wire 115, and the equivalent capacitance chip 114 is connected to the carrier substrate 111 via a bonding wire 116.

The semiconductor chip 112, the equivalent capacitance chip 114, and the bonding wires 115 and 116 are encapsulated by a sealing member 118, so that a semiconductor package is constructed. Furthermore, protruding electrodes 119 for mounting the semiconductor package on a board are formed on the back surface of the carrier substrate 111.

Because the semiconductor chip 112 and the equivalent capacitance chip 114 are mounted on the same semiconductor package, even when any of the core blocks 1 to 3 is stopped, the equivalent capacity of the semiconductor chip 112 can be made equal to the sum of the equivalent capacities 4 to 6 of the core blocks 1 to 3 without taking any measures on the board on which the semiconductor package is mounted. Furthermore, it is possible to reduce the power supply impedance to be equal to or smaller than a defined value and prevent the operating frequency from being matched with the antiresonance frequency.

### Seventh Embodiment

FIG. 8 is a cross-sectional view explaining a general configuration of a semiconductor device according to a seventh embodiment of the present invention.

In FIG. 8, a semiconductor chip 122 is mounted with face up on a carrier substrate 121. Furthermore, an equivalent capacitance chip 124a and a semiconductor chip 124b are mounted with face up on the semiconductor chip 122 via spacer layers 123a and 123b, respectively.

Similarly to the semiconductor chip 102 shown in FIG. 6 for example, it is possible to form the core blocks 1 to 3, the power-supply switches 11 to 13, and the power line 24a on the semiconductor chip 122. Furthermore, similarly to the equivalent capacitance chip 104 shown in FIG. 6 for example, it is possible to form the capacitors 7 to 9, the selection switches 14 to 16, and the power line 24b on the equivalent capacitance chip 124a. Moreover, its possible to mount, on the semiconductor chip 124b, a control circuit that controls a connection state between the capacitors 7 to 9 and the power line 24b depending on a connection state between the core blocks 1 to 3 and the power line 24a.

The semiconductor chip 122 is connected to the carrier substrate 121 via bonding wires 125a and 125b, and the equivalent capacitance chip 124a is connected to the carrier substrate 121 via a bonding wire 126a, and the semiconductor chip 124b is connected to the carrier substrate 121 via a bonding wire 126b. Furthermore, the equivalent capacitance chip 124a is connected to the semiconductor chip 122 via bonding wires 127a, and the semiconductor wire 124b is connected to the semiconductor chip 122 via bonding wires 127b.

The semiconductor chips 122 and 124b, the equivalent capacitance chip 124a, and the bonding wires 125a, 125b, 126a, 126b, 127a, and 127b are encapsulated by a sealing member 128, so that a semiconductor package is constructed. Furthermore, protruding electrodes 129 for mounting the semiconductor package on a board are formed on the back surface of the carrier substrate 121.

Because the semiconductor chips 122 and 124b and the equivalent capacitance chip 124a are mounted on the same semiconductor package, even when any of the core blocks 1 to 3 is stopped, the equivalent capacity of the semiconductor chip 122 can be made equal to the sum of the equivalent capacities 4 to 6 of the core blocks 1 to 3 without taking any measures on the board on which the semiconductor package is mounted. Furthermore, it is possible to reduce the power supply impedance to be equal to or smaller than a defined value and prevent the operating frequency from being matched with the antiresonance frequency.

### Eighth Embodiment

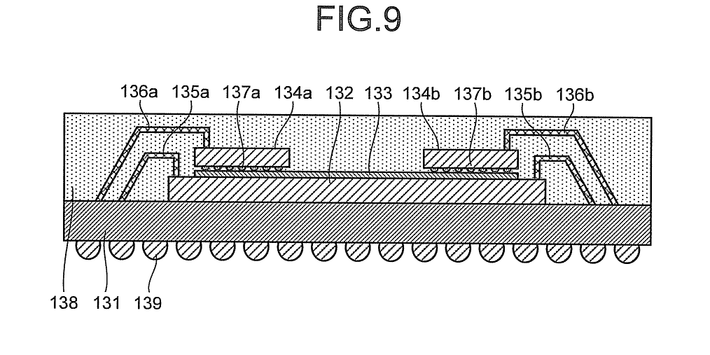

FIG. 9 is a cross-sectional view explaining a general configuration of a semiconductor device according to an eighth embodiment of the present invention.

In FIG. 9, a semiconductor chip 132 is mounted with face up on a carrier substrate 131. The semiconductor chip 132 is formed as a chip size package, and a wiring layer 133 is formed on the semiconductor chip 132. An equivalent capacitance chip 134a and a semiconductor chip 134b are mounted with face down on the wiring layer 133 on the semiconductor chip 132 via protruding electrodes 137a and 137b, respectively. Through electrodes that pierce through the equivalent capacitance chip 134a and the semiconductor chip 134b are respectively formed on the equivalent capacitance chip 134a and the semiconductor chip 134b, so that the top surface and the back surface of the equivalent capacitance chip 134a are electrically connected to each other and the top surface and the back surface of the semiconductor chip 134b are electrically connected to each other.

Similarly to the semiconductor chip 102 shown in FIG. 6 for example, it is possible to form the core blocks 1 to 3, the power-supply switches 11 to 13, and the power line 24a on the semiconductor chip 132. Furthermore, similarly to the equivalent capacitance chip 104 shown in FIG. 6 for example, it is possible to form the capacitors 7 to 9, the selection switches 14 to 16, and the power line 24b on the equivalent capacitance chip 134a. Moreover, it is possible to mount, on the semiconductor chip 134b, a control circuit that controls a connection state between the capacitors 7 to 9 and the power line 24b depending on a connection state between the core blocks 1 to 3 and the power line 24a.

The semiconductor chip 132 is connected to the carrier substrate 131 via bonding wires 135a and 135b. The equivalent capacitance chip 134a is connected to the carrier substrate 131 via a bonding wire 136a. The semiconductor chip 134b is connected to the carrier substrate 131 via a bonding wire 136b.

The semiconductor chips 132 and 134b, the equivalent capacitance chip 134a, and the bonding wires 135a, 135b, 136a, and 136b are encapsulated by a sealing member 138, so that a semiconductor package is constructed. Furthermore, protruding electrodes 139 for mounting the semiconductor package on a board are formed on the back surface of the carrier substrate 131.

Because the semiconductor chips 132 and 134b and the equivalent capacitance chip 134a are mounted on the same semiconductor package, even when any of the core blocks 1 to 3 is stopped, the equivalent capacity of the semiconductor chip 132 can be made equal to the sum of the equivalent capacities 4 to 6 of the core blocks 1 to 3 without taking any measures on the board on which the semiconductor package is mounted. Furthermore, it is possible to reduce the power supply impedance to be equal to or smaller than a defined value and prevent the operating frequency from being matched with the antiresonance frequency.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a core block formed on a semiconductor chip and constructed of an integrated circuit that can operate independently;
a power-supply switch formed on the semiconductor chip for connecting or disconnecting the core block to or from a power line;
a capacitor formed on the semiconductor chip and connected to the power line in parallel to the core block; and
a selection switch formed on the semiconductor chip for connecting or disconnecting the capacitor to or from the power line.

2. The semiconductor device of claim 1, wherein
the capacitor is connected to the power line so that an operating frequency does not match an antiresonance frequency depending on a connection state between the core block and the power line.

3. The semiconductor device of claim 1, wherein
a capacity of the capacitor is equal to an equivalent capacity of the core block, and
the capacitor is connected to the power line when the core block is disconnected from the power line.

4. The semiconductor device of claim 2, wherein
the core block is provided in plurality on the semiconductor chip, and
the semiconductor chip includes a plurality of capacitors corresponding to respective capacities of the core blocks.

5. The semiconductor device of claim 1, further comprising:
a control circuit that controls a connection state between the capacitor and the power line depending on a connection state between the core block and the power line.

6. The semiconductor device of claim 1, wherein
the power line is formed along an outer circumference of the semiconductor chip.

7. A semiconductor device comprising:
a semiconductor chip on which a core block is formed, the core block being constructed of an integrated circuit that can operate independently;
a power-supply switch formed on the semiconductor chip for connecting or disconnecting the core block to or from a power line;
a capacitive chip on which a capacitor is formed, the capacitor being connected to the power line in parallel to the core block;
a selection switch formed on the capacitive chip for connecting or disconnecting the capacitor to or from the power line; and
a semiconductor package for encapsulating the semiconductor chip and the capacitive chip.

8. The semiconductor device of claim 7, wherein
the capacitive chip is mounted with face up on the semiconductor chip.

9. The semiconductor device of claim 7, wherein
the capacitive chip is mounted with face down on the semiconductor chip.

10. The semiconductor device of claim 7, wherein
the capacitor is connected to the power line so that an operating frequency does not match an antiresonance frequency depending on a connection state between the core block and the power line.

11. The semiconductor device of claim 7,
wherein
a capacity of the capacitor is equal to an equivalent capacity of the core block, and
the capacitor is connected to the power line when the core block is disconnected from the power line.

12. The semiconductor device of claim 11, wherein
the core block is provided in plurality on the semiconductor chip, and
the capacitive chip includes a plurality of capacitors corresponding to respective capacities of the core blocks.

13. The semiconductor device of claim 7, further comprising:
a control circuit that controls a connection state between the capacitor and the power line depending on a connection state between the core block and the power line.

14. A semiconductor device comprising:
a first semiconductor chip on which a core block is formed, the core block being constructed of an integrated circuit that can operate independently;
a power-supply switch formed on the first semiconductor chip for connecting or disconnecting the core block to or from a power line;
a capacitive chip on which a capacitor is formed, the capacitor being connected to the power line in parallel to the core block;
a selection switch formed on the capacitive chip for connecting or disconnecting the capacitor to or from the power line;
a second semiconductor chip on which a control circuit is formed, the control circuit being configured to control a connection state between the capacitor and the power line depending on a connection state between the core block and the power line; and
a semiconductor package for encapsulating the first semiconductor chip, the second semiconductor chip, and the capacitive chip.

15. The semiconductor device of claim 14, wherein
the capacitive chip and the second semiconductor chip are mounted with face up on the first semiconductor chip.

16. The semiconductor device of claim 14, wherein
the capacitive chip and the second semiconductor chip are mounted with face down on the first semiconductor chip.

17. The semiconductor device of claim 14, wherein
the capacitor is connected to the power line so that an operating frequency does not match an antiresonance frequency depending on a connection state between the core block and the power line.

18. The semiconductor device of claim 14, wherein
a capacity of the capacitor is equal to an equivalent capacity of the core block, and
the capacitor is connected to the power line when the core block is disconnected from the power line.

19. The semiconductor device of claim 18, wherein
the core block is provided in plurality on the first semiconductor chip, and
the capacitive chip includes a plurality of capacitors corresponding to respective capacities of the core blocks.

20. The semiconductor device of claim 14, wherein
the power line is formed along an outer circumference of the first semiconductor chip.
